(19) United States
(12) Patent Application Publication
(10) Pub. No.: US 2026/0190306 A1
(43) Pub. Date: Jul. 2, 2026

(54) HEAT SINK FOR RELEASABLY SECURING TO A COOLING UNIT, AND COOLING UNIT WITH RELEASABLY SECURABLE HEAT SINKS

(71) Applicant: TRUMPF HÜTTINGER GMBH + CO. KG, Freiburg (DE)

(72) Inventors: Guido Dieter HODAPP, Emmendingen (DE); Felix MUSSLER, Hohberg (DE)

(21) Appl. No.: 19/550,330

(22) Filed: Feb. 26, 2026

Related U.S. Application Data
(63) Continuation of application No. PCT/EP2024/074321, filed on Aug. 30, 2024.

(30) Foreign Application Priority Data
Sep. 1, 2023 (DE) 10 2023 123 664.4

(51) Int. Cl. H05K 7/20

(52) U.S. Cl. CPC H05K 7/20927; H05K 7/209

(57) ABSTRACT

A heat sink for dissipating heat from an electric unit, the heat sink including a cooling channel, a first cooling wall arranged on a side of the cooling channel facing the electric unit, and a coolant feed and discharge which are both fluidically connected to the cooling channel configured for supplying and discharging cooling liquid. The heat sink is configured such that the electric unit can be mechanically and thermally connected to the first cooling wall and the heat sink can be releasably secured to a cooling unit including a first fluid port and a second fluid port. The heat sink is further configured such that when the heat sink is secured to the cooling unit, a fluid-tight seal is simultaneously created between a first and second fluidic connection, and the heat sink can be mechanically fixedly connected to the electric unit.

### CROSS REFERENCE TO RELATED APPLICATIONS

This application is a continuation of International Application No. PCT/EP2024/074321 (WO 2025/046089A1), filed on Aug. 30, 2024, and claims benefit to German Patent Application No. DE 10 2023 123 664.4, filed on Sep. 1, 2023. The aforementioned applications are hereby incorporated by reference herein.

### FIELD

The invention relates to a heat sink for dissipating heat from a unit to be cooled, to an electronic assembly, a cooling unit and a cooling device for supplying a heat sink with coolant, to a method for assembling a cooling device starting from a heat sink and a cooling unit, and to an electrical power converter for an industrial process assembly.

### BACKGROUND

The present disclosure relates to the field of electrical power conversion for special power-intensive and instability-prone industrial processes, such as plasma excitation, plasma coating processes, gas laser excitation, particle accelerators, charging and discharging systems for large batteries, such as flow batteries, melting of solids, heating and/or gasification of liquids by, for example, microwave energy or induction heating. A feature common to all of these processes is that they are designed to generate and accelerate charged atomic particles in a gas and/or plasma environment or liquid. Another feature common to all of these processes is that they have a high power consumption which is in the range of 1 kW or more, in particular 10 kW or more, preferably 100 kW or more. Many of these processes also have a very high requirement for the stability of the power supply because the processes are highly complex, such as semiconductor manufacturing using plasma processes and/or heating by electromagnetic fields. Typically, power is converted from a mains frequency, which is in the range of approximately 50 Hz to 60 Hz, to different frequencies, which can range from 1 kHz to 200 MHz. Conversion to direct-current power, also called DC power, is also conceivable. Converting electrical power to other frequencies requires a plurality of electronic components and assemblies, but in particular power semiconductor devices such as transistors or diodes designed for currents ≥10 A and voltages ≥400 V. These electronic components and assemblies generate waste heat during operation. The waste heat often occurs over a very limited area of just a few mm². It is a particular challenge to dissipate this waste heat in order to protect the components and/or assemblies from destruction due to overheating. Often, very large and material-intensive heat sinks are used for this purpose, the production of which is very expensive.

In the prior art, the heat is dissipated by cooling using a cooling plate. When cooling with such a conventional cooling plate, the heat transfer from the electrical component, which may have a copper layer, to the cooling medium is achieved by applying a material, such as thermal paste, to the thermal interface, thereby dissipating the generated heat. Such heat interface material is disadvantageous. Firstly, it constitutes another heat transfer with thermal resistance, and secondly, it is subject to wear, which gradually degrades its effectiveness during operation. The surface area of the cooling plate is also increased, or the number and performance of the components are reduced, in order to dissipate a larger amount of heat or generate a smaller amount of heat. Neither of the two option is sufficient. Since the installation space in the housing of such a power supply is limited, the cooling surface cannot be expanded indefinitely. Reducing the performance of individual components is also not a viable solution. Overall, inadequate cooling of the electrical components results in costs.

In many technical applications, particularly in the field of power electronics, there is a need to undo a unit to be cooled, such as a semiconductor element or semiconductor assembly, from the rest of the assembly when necessary. To enable the unit to be releasably attached to the heat sink, the units to be cooled are often releasably attached to the associated heat sinks, for example using thermal paste. This results in the disadvantage of comparatively poor thermal coupling between the unit to be cooled and the heat sink.

### SUMMARY

In an embodiment, the present disclosure provides a heat sink for dissipating heat from an electric unit to be cooled, the heat sink comprising a cooling channel, a first cooling wall arranged on a side of the cooling channel facing the electric unit to be cooled, and a coolant feed and a coolant discharge which are both fluidically connected to the cooling channel configured for supplying and discharging cooling liquid. The heat sink is configured such that the electric unit to be cooled can be mechanically and thermally connected to the first cooling wall and the heat sink can be releasably secured to a cooling unit comprising a first fluid port and a second fluid port. The heat sink is further configured such that a first fluidic connection is configured to be produced between the coolant feed of the heat sink and the first fluid port of the cooling unit when the heat sink is secured to the cooling unit, and a second fluidic connection is configured to be produced between the coolant discharge of the heat sink and the second fluid port of the cooling unit when the heat sink is secured to the cooling unit. The heat sink is further configured such that when the heat sink is secured to the cooling unit, a fluid-tight seal is simultaneously created between the first fluidic connection and the second fluidic connection, and the heat sink can be mechanically fixedly connected to the electric unit to be cooled, the electric unit to be cooled being fixedly connected to a circuit board via a connection.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a longitudinal section through a unit to be cooled, a heat sink, and a cooling unit that supplies the heat sink with coolant;

FIG. 2 shows a circuit board with two units to be cooled arranged on the circuit board, wherein the circuit board is releasably attachable to a cooling unit;

FIG. 3 shows an industrial process assembly, preferably a plasma process assembly or a heating assembly with a heat sink;

FIG. 4a shows a sectional view of the circuit board with the units to be cooled arranged thereon together with a carrier unit;

FIG. 4b shows a view of the entire carrier unit with the circuit board arranged thereon;

FIG. 5 shows another view of the carrier unit in longitudinal section;

FIG. 6 shows a sectional view of the carrier unit from an oblique angle from an underside, in which a cooling insert and pipes for the fluid supply of the cooling insert can be seen; and

FIG. 7 shows a sectional view of the entire carrier unit from an oblique angle from the underside, in which the cooling insert, the piping, and the coolant connections can be seen.

### DETAILED DESCRIPTION

In an embodiment, the present disclosure provides a heat sink, an electronic assembly, a cooling device and a cooling unit that enables improved thermal coupling between the heat sink and a unit to be cooled and improves ease of maintenance.

The foregoing can be achieved by using a heat sink to dissipate heat from a unit to be cooled, in particular an electric unit, preferably a semiconductor assembly. The heat sink comprises a cooling channel and a first cooling wall arranged on the side of the cooling channel facing the unit to be cooled. Furthermore, the heat sink comprises a coolant feed and a coolant discharge that are both fluidically connected to the cooling channel for the supply and discharge of coolant, in particular cooling liquid, preferably cooling water. The heat sink is configured in such a way that the unit to be cooled can be mechanically and thermally connected to the first cooling wall. Furthermore, the heat sink is configured in such a way that the heat sink can be releasably secured to a cooling unit comprising a first fluid port and a second fluid port, and that when the heat sink is secured to the cooling unit, a first fluidic connection can be produced between the coolant feed of the heat sink and the first fluid port of the cooling unit, as well as a second fluidic connection between the coolant discharge of the heat sink and the second fluid port of the cooling unit. The heat sink is configured in such a way that when the heat sink is secured to the cooling unit, a fluid-tight seal is simultaneously created between the first fluidic connection and the second fluidic connection. The heat sink is further configured in such a way that it can be mechanically connected to the unit to be cooled that is connected to a circuit board by one, in particular a number of, connections. In this way, the unit to be cooled can be cooled very effectively by the heat sink. The heat sink can thus remain on the unit to be cooled when the circuit board is removed along with the unit to be cooled and, for example, separated from the cooling unit. This allows heat transfer between the unit to be cooled and the heat sink to be configured very effectively and reliably.

A ‘fluidic connection’ is a connection designed to allow a fluid to flow through it.

A ‘fluid port’ is an opening designed to allow a fluid to pass through it, and to allow a component with a similar opening to be connected to it, such that this fluid can be guided through these openings.

The heat sink enables the heat sink to be releasably secured in a cooling unit. The cooling unit is configured to supply coolant to the heat sink and to discharge coolant. The heat sink can, for example, be configured in such a way that fluid-tight fluidic connections can be produced between the heat sink and the cooling unit when the heat sink is secured to the cooling unit. The heat sink can be removed, along with the unit to be cooled attached to the heat sink, from the cooling unit when necessary. This is particularly advantageous from the standpoint of maintenance and repair. According to embodiments of the present disclosure, the unit to be cooled can, for example, be removed from the cooling unit together with the heat sink.

This development makes it possible, for example, to mechanically fixedly connect the unit to be cooled to the heat sink. The result of the development is preferably to make the connection between the unit to be cooled and the heat sink as thin and using as little additional material as possible. In the course of the considerations, simulations and experiments for this development, it was found that this is in particular possible when the heat sink with fluid flowing through it is fixedly connected, in particular by a material bond, to the unit to be cooled. This can be achieved, for example, by soldering, sintering, pressing or direct copper bonding (DCB). The term ‘fixedly’ here can mean: ‘only destructively detachable’, i.e., using connecting means that cannot be undone even with tools without destroying either the unit 10 to be cooled or the heat sink 5 or both components. In this case too, the unit to be cooled can be removed together with the heat sink from the cooling unit, for example for maintenance purposes. Mechanically fixedly attaching the unit to be cooled to the heat sink can achieve improved thermal coupling between the unit to be cooled and the heat sink, and better heat transfer from the unit to be cooled to the heat sink.

Furthermore, the development concerns an electronic assembly which comprises a heat sink as described above and a unit to be cooled that is mechanically fixedly connected to the heat sink.

During development, the electronic assembly, which comprises the heat sink and the unit to be cooled that is mechanically fixedly connected to the heat sink, can, for example, be inserted into the cooling unit and removed from the cooling unit as a whole. This enables access to the unit to be cooled.

The development also relates to a cooling unit for supplying a heat sink that has a coolant feed and a coolant discharge, with coolant, in particular cooling liquid, preferably cooling water. The cooling unit has a first flow channel and a second flow channel. Furthermore, the cooling unit comprises a first fluid port that is fluidically connected to the first flow channel, and a second fluid port that is fluidically connected to the second flow channel. The cooling unit is configured in such a way that the heat sink can be releasably secured to the cooling unit and that, when the heat sink is secured to the cooling unit, a first fluidic connection can be produced between the coolant feed of the heat sink and the first fluid port of the cooling unit, as well as a second fluidic connection between the coolant discharge of the heat sink and the second fluid port of the cooling unit. Furthermore, the heat sink is configured in such a way that, when the heat sink is secured to the cooling unit, a fluid-tight seal is simultaneously created between the first fluidic connection and the second fluidic connection. The heat sink is further configured in such a way that it can be mechanically connected to the unit to be cooled that is connected to a circuit board by one, in particular a number of, connections. In this way, the unit to be cooled can be cooled very effectively by the heat sink. The heat sink can thus remain on the unit to be cooled when the circuit board is removed along with the unit to be cooled and, for example, separated from the cooling unit. This allows heat transfer between the unit to be cooled and the heat sink to be configured very effectively and reliably.

The cooling unit can be designed, for example, to supply a single heat sink with coolant, but it can also be designed, for example, to supply a plurality of heat sinks with coolant and to discharge the coolant after it has flowed through the heat sinks. In this way, a cooling system is created that enables access to the cooling units when necessary.

Furthermore, the development concerns a cooling device comprising a cooling unit as described above and a heat sink releasably connected to the cooling unit as described above.

The development moreover relates to an electrical power converter for an industrial process assembly, preferably a plasma process assembly or a heating assembly having:
a heat sink, as described above and below,
a circuit board,
a unit to be cooled, in particular an electric unit, preferably a semiconductor assembly, preferably having a power semiconductor component,
further electronic components,
   wherein the further electronic components and the unit to be cooled are arranged on or at a circuit board and are connected to electrical contacts,
   wherein the unit to be cooled has a fixed, in particular materially bonded, connection to the heat sink and the unit to be cooled is simultaneously fixedly connected to the circuit board by a number of connections, in particular by soldering.

In an aspect, the electrical power converter has a cooling unit as described here.

In an aspect, the electrical power converter has a cooling device as described here.

In an aspect, the electrical power converter has one or more of the heat sinks described here as further heat sink(s).

In an aspect, the electrical power converter has one or more of the electronic assemblies described here as further electronic assemblies.

A preferred outcome of the development is to make the connection between the unit to be cooled and the heat sink as thin and using as little additional material as possible. In the course of the considerations, simulations and experiments for this development, it was found that this is in particular possible when the heat sink with fluid flowing through it is fixedly connected, in particular by a material bond, to the unit to be cooled. This can be achieved, for example, by soldering, sintering, pressing or direct copper bonding (DCB). The term ‘fixedly’ here can mean: ‘only destructively detachable’, i.e., using connection means that cannot be undone even with tools without destroying either the unit to be cooled or the heat sink, or both components.

The development furthermore relates to a method for assembling a cooling device starting from a heat sink for dissipating heat from a unit to be cooled, in particular an electric unit, preferably a semiconductor assembly, and a cooling unit. The heat sink has a cooling channel, a coolant feed fluidically connected to the cooling channel, and a coolant discharge fluidically connected to the cooling channel. The cooling unit comprises a first fluid port and a second fluid port. The method comprises a step of releasably securing the heat sink to the cooling unit, wherein, when the heat sink is secured to the cooling unit, a first fluidic connection is produced between the coolant feed of the heat sink and the first fluid port of the cooling unit, as well as a second fluidic connection between the coolant discharge of the heat sink and the second fluid port of the cooling unit. When the heat sink is secured to the cooling unit, a fluid-tight seal is simultaneously created between the first fluidic connection and the second fluidic connection.

Advantageous embodiments and developments, which can be used individually or in combination, are the subject matter of the following description.

The coolant feed and coolant discharge of the heat sink are preferably arranged on the side of the heat sink facing away from the unit to be cooled. This makes it possible, for example, to fluidically contact the heat sink on the side of the heat sink facing away from the unit to be cooled.

In an aspect, the heat sink can be releasably secured to the cooling unit by way of at least one securing means, preferably at least one screw. The at least one securing means can preferably be configured to produce the fluidic connections between the heat sink and the cooling unit in such a way that a fluid-tight seal is achieved. The securing means can preferably be a securing means that can be easily undone with or without tools.

The connection between the heat sink and the cooling unit can be in particular be more easily undone than the connection between the heat sink and the unit to be cooled.

The connection between the heat sink and the cooling unit can in particular be made in a single step with the sealing of the fluid port(s).

It is advantageous if the fluid-tight seal of the first fluidic connection and the second fluidic connection can be produced with at least one securing means that is accessible from the side of the first cooling wall. The fact that at least one securing means is accessible from the side of the first cooling wall makes the heat sink easier to handle on insertion and removal from the cooling unit.

In an aspect, the heat sink can be pressed against the cooling unit by way of at least one securing means in such a way that fluid-tight fluidic connections can be produced between the first fluid port of the cooling unit and the coolant feed of the heat sink and between the second fluid port of the cooling unit and the coolant discharge of the heat sink. For example, at least one securing means can be configured in such a way that, when the heat sink is secured to the cooling unit, a contact force can be generated which presses the first and second fluid ports of the cooling unit against the coolant feed and discharge of the heat sink.

It is advantageous for the cooling device to comprise a first sealing element designed to create a liquid-tight first fluidic connection when the heat sink is secured to the cooling unit. By way of the first sealing element, a fluid-tight first fluidic connection can be produced, for example, when the heat sink is secured to the cooling unit. For example, when the heat sink is pressed onto the cooling unit, it can be deformed in such a way that the connection between the first cooling port and the coolant feed is sealed. The first sealing element is preferably a first sealing ring that surrounds the first fluid port.

In an aspect, the cooling device comprises a second sealing element designed to produce a liquid-tight second fluidic connection when the heat sink is secured to the cooling unit. By way of the second sealing element, a fluid-tight second fluidic connection can be produced, for example, when the heat sink is secured to the cooling unit. The second sealing element is preferably a second sealing ring that surrounds the second fluid port.

In an aspect, the heat sink is configured in such a way that, when the heat sink is secured to the cooling unit, a cooling flow can be produced from the first fluid port to the coolant feed via the cooling channel and the coolant discharge to the second fluid port. In this way, the heat sink can, for example, be supplied with coolant from the cooling unit.

In an aspect, the heat sink consists of or comprises metal, preferably copper. The high thermal conductivity of copper enables effective heat dissipation from the unit to be cooled.

In an aspect, the unit to be cooled is mechanically and thermally connected to the heat sink. An electronic assembly constructed in this way has the heat sink with one or more of the features described here. The unit to be cooled that is mechanically fixedly connected to the heat sink is designed to be simultaneously fixedly connected to a circuit board, in particular by soldering, in particular by a number of, connections.

In an aspect, the unit to be cooled is connected to the heat sink by at least one of the following: by at least one soldered connection, by at least one welded connection, by sintering. For example, if the heat sink is fixedly soldered to the unit to be cooled, the soldering enables improved thermal coupling. Improved thermal coupling between the heat sink and the unit to be cooled can also be achieved, for example, by way of a welded connection or by sintering.

In an aspect, the unit to be cooled is connected to the heat sink by way of a layer of thermal paste. In this case too, it can be advantageous to be able to remove the heat sink from the cooling unit when necessary.

In an aspect, the electronic assembly described above has a circuit board to which the unit to be cooled is fixedly mechanically connected. This fixed mechanical connection can be achieved, for example, by soldering electrical terminals of the unit to be cooled to the circuit board. In this embodiment, the circuit board, the unit to be cooled, and the heat sink form a structural unit that can, for example, be inserted into the cooling unit as a whole.

In an aspect, the electronic assembly comprises a plurality of units to be cooled that have a fixed mechanical connection to the circuit board, as well as a plurality of heat sinks. The electronic assembly with its plurality of heat sinks can be inserted into the cooling unit as a whole. The cooling unit preferably has a plurality of receptacles designed to accommodate the plurality of heat sinks. The fact that the electronics assembly can be removed from the cooling unit for example facilitates maintenance.

In an aspect, the cooling unit has at least one receiving device for at least one securing means.

In an aspect, the heat sink can be secured by way of at least one securing means accessible from the side of the first cooling wall, which securing means engages in the at least one receiving device. If the at least one securing means engages in the at least one receiving device on the side of the cooling unit, the heat sink can, for example, be secured to the cooling unit.

In an aspect, the fluid-tight seal of the first fluidic connection and the second fluidic connection can be achieved with at least one securing means that is accessible from the side of the unit to be cooled. If at least one securing means is accessible from the side of the unit to be cooled, inserting and removing the heat sink from the cooling unit can be facilitated.

It is advantageous for the cooling unit to have a receptacle for the heat sink into which the heat sink can be inserted. This enables, for example, precisely fitting fixation of the heat sink to the cooling unit.

In an aspect, the cooling unit is configured to supply coolant to a plurality of heat sinks and to remove coolant from the plurality of heat sinks.

In an aspect, the cooling unit has a plurality of receptacles into which a plurality of heat sinks can be inserted. As a result, an electronic assembly that has a plurality of heat sinks can be inserted as a whole into the receptacles of the cooling unit.

In an aspect, the cooling unit consists entirely of or partially comprises metal or consists entirely of or partially comprises a plastics material.

In an aspect, grooves are provided within the cooling unit into which pipes can be pressed. The pipes can, for example, comprise a first flow channel for supplying coolant and a second flow channel for discharging coolant.

In an aspect, the wall of the pipes consists entirely of or predominantly of a material, preferably copper, which has a higher thermal conductivity compared to other regions of the cooling unit, or comprises such a material. The high thermal conductivity of the pipe walls can, for example, further improve heat dissipation from the unit to be cooled.

In an aspect, the cooling unit comprises a distribution unit that has the first fluid port and the second fluid port. The distribution unit is preferably configured to supply at least one heat sink with coolant and to discharge the returning coolant.

It is advantageous for the distribution unit to be configured as a cooling insert that consists of or comprises a material, preferably copper, that has a higher thermal conductivity compared to other regions of the cooling unit. For example, the cooling insert can be in thermal contact with the heat sink, such that heat dissipation from the heat sink is improved by the thermal contact with the cooling insert. This saves costs and weight, as the entire carrier unit does not have to be made from the more costly and usually heavier material, such as copper.

In an aspect, the cooling unit comprises a carrier unit. The distribution unit can be inserted into the carrier unit.

In an aspect, the carrier unit consists entirely of or partially comprises metal, preferably aluminum.

In an aspect, within the cooling device, a cooling flow can be produced from the first fluid port to the coolant feed via the cooling channel and the coolant discharge to the second fluid port. This cooling flow can be used, for example, to remove the heat generated by the unit to be cooled.

In an aspect, the cooling unit is designed to supply coolant, in particular cooling liquid, preferably cooling water, to the heat sink via the first fluid port and to discharge coolant from the heat sink via the second fluid port.

Further advantageous configurations are described in more detail below with reference to a number of exemplary embodiments shown schematically in the drawings, to which the development is not limited.

In the following description of preferred embodiments of the present development, identical reference numerals designate identical or comparable components.

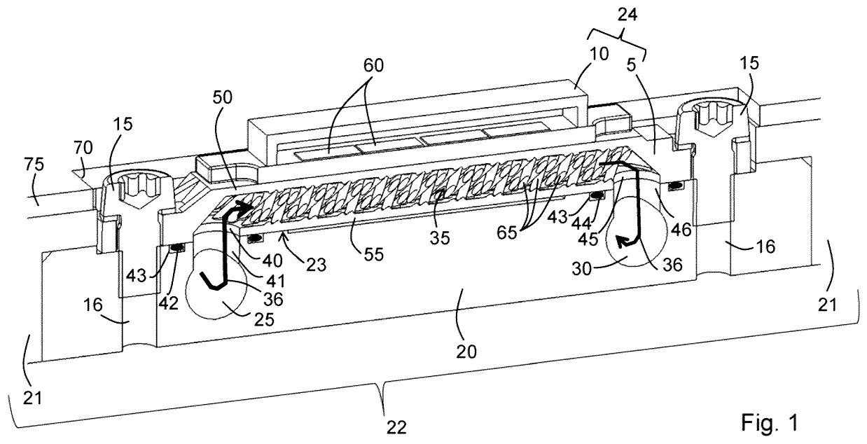

FIG. 1 shows a cooling device in longitudinal section. The cooling device comprises a heat sink 5 that is configured to cool a unit 10 to be cooled that is attached to the heat sink 5. The unit 10 to be cooled can in particular be an electric unit, preferably a semiconductor assembly.

The heat sink 5 is releasably connected to a cooling unit 22. In the example shown in the figures, the cooling unit 22 comprises a distribution unit 20 designed to supply the heat sink 5 with coolant. Furthermore, the cooling unit 22 comprises a carrier unit 21 into which the distribution unit 20 is inserted. The cooling unit 22 has a receptacle 23 into which the heat sink 5 can be releasably inserted. The heat sink 5 is then secured to the cooling unit 22 by way of at least one securing means 15, preferably by way of one or more screws. The cooling unit 22 has at least one receiving device 16 for the at least one securing means 15. To separate the heat sink 5 from the cooling unit 22, at least one securing means 15 is first undone. The heat sink 5, together with the unit 10 to be cooled attached thereto, can then be removed from the receptacle 23 of the cooling unit 22.

The unit 10 to be cooled is preferably mechanically and thermally connected to the heat sink 5. The unit 10 to be cooled can be connected to the heat sink 5, for example, by way of one or more soldered connections. The unit 10 to be cooled can be connected to the heat sink 5, for example by way of sintering. Alternatively, the unit 10 to be cooled can be welded to the heat sink 5. As another, albeit less advantageous, alternative, the unit 10 to be cooled could also be connected to the heat sink 5 by way of a layer of thermal paste. The result of the development, however, is to make the connection between the unit 10 to be cooled and the heat sink 5 as thin and using as little additional material as possible. In the course of the considerations, simulations and experiments for this development, it was found that this is in particular possible when the heat sink with fluid flowing through it is fixedly connected, in particular by a material bond, to the unit 10 to be cooled. This can be achieved, for example, by soldering, sintering, pressing or direct copper bonding (DCB). The term ‘fixedly’ here can mean: ‘only destructively detachable’, i.e., using connecting means that cannot be undone even with tools without destroying either the unit 10 to be cooled or the heat sink 5 or both components. It was further recognized that such a solution will only be feasible if it is possible to find a new solution for the interchangeability of the component circuit board 75 with electronic components and, in particular, with the cooling unit 10 secured thereto. This is achieved with the disclosed heat sink 5.

The heat sink 5 and the unit 10 to be cooled that is mechanically fixedly connected to the heat sink 5 together form an electronic assembly 24. This electronic assembly 24 can be inserted into the receptacle 23 of the cooling unit 22 and removed from this receptacle 23.

The cooling unit 22 is designed to supply coolant to the heat sink 5 attached to the cooling unit 22 and to discharge the coolant again after the coolant has flowed through the heat sink 5. A first flow channel 25 through which coolant can be supplied to the heat sink 5 can be seen within the cooling unit 22. A second flow channel 30 through which the coolant can be discharged can be seen within the cooling unit 22. The heat sink 5 has a cooling channel 35 through which the coolant can flow. A coolant feed 40 is provided at a first end of the cooling channel 35 and a coolant discharge 45 is provided at the second end of the cooling channel 35 opposite the first end. The coolant feed 40 and the coolant discharge 45 are fluidically connected to the cooling channel 35.

The cooling unit 22 comprises a first fluid port 41 that is fluidically connected to the first flow channel 25, and a second fluid port 46 that is fluidically connected to the second flow channel 30. When the heat sink 5 is inserted and subsequently secured in the receptacle 23, a first fluidic connection is produced between the first fluid port 41 and the coolant feed 40, as well as a second fluidic connection between the second fluid port 46 and the coolant discharge 45.

To seal the first fluidic connection, a first sealing ring 42 is arranged in a groove 43 between the cooling unit 22 and the heat sink 5, wherein the sealing ring 42 entirely surrounds the first fluid port 41. A second sealing ring 44 that entirely surrounds the second fluid port 46 is likewise provided at the second fluid port 46 and is arranged in a groove 43 between the cooling unit 22 and the heat sink 5. When the at least one securing means 15 is secured, for example when the at least one screw is tightened, the heat sink 5 is pressed against the first fluid port 41 and the first sealing ring 42 as well as against the second fluid port 46 and the second sealing ring 44. This application of pressure produces a liquid-tight first fluidic connection and a liquid-tight second fluidic connection between the cooling unit 22 and the heat sink 5.

As shown in FIG. 1, a cooling flow 36 can be produced within the cooling device. The coolant flows from the first flow channel 25 via the first fluid port 41 and the coolant feed 40 into the cooling channel 35. The coolant flows through the cooling channel 35 and is discharged again via the coolant discharge 45, the second fluid port 46 and the second flow channel 30.

The heat sink 5 has a first cooling wall 50 on the side facing the unit 10 to be cooled. On the side of the heat sink 5 facing away from the unit 10 to be cooled, the cooling channel 35 is bounded by a second cooling wall 55 that is opposite the first cooling wall 50. Preferably, the second cooling wall 55 is configured parallel to the first cooling wall 50.

In the example shown in FIG. 1, the unit 10 to be cooled comprises an arrangement of transistors 60. The heat generated during operation of the transistors 60 is dissipated via the coolant flowing in the cooling channel 35.

To improve thermal exchange between the coolant flowing through the cooling channel 35 and the heat sink 5, a plurality of cooling pins 65 that extend into the cooling channel 35 from the first cooling wall 50 and/or from the second cooling wall 55 can be arranged inside the cooling channel 35. The cooling pins 65 have coolant flowing around them and ensure improved thermal coupling between the heat sink 5 and the coolant.

It can also be seen in FIG. 1 that the unit 10 to be cooled, together with the heat sink 5 arranged therebelow, is arranged within a first recess 70 of a circuit board 75.

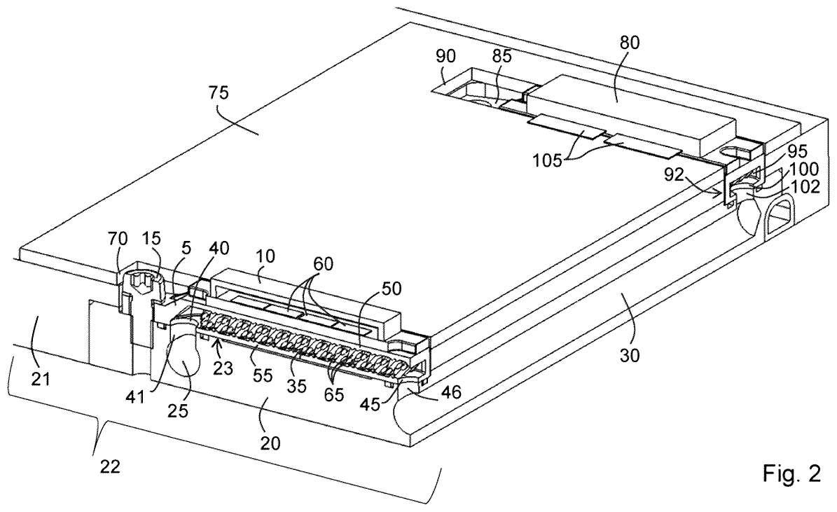

The arrangement of the unit 10 to be cooled within the first recess 70 of the circuit board 75 can clearly be seen in FIG. 2. FIG. 2 shows the circuit board 75 which is arranged on the cooling unit 22. The unit 10 to be cooled is shown in longitudinal section together with the associated heat sink 5 within the first recess 70 of the circuit board 75. The heat sink 5 is inserted into the receptacle 23 of the cooling unit 22.

In addition to the unit 10 to be cooled, another unit 80 to be cooled can be seen in FIG. 2 together with a further heat sink 85 arranged therebelow. The further unit 80 to be cooled is arranged within a further recess 90 provided in the circuit board 75 and the associated further heat sink 85 is inserted into a further receptacle 92 of the cooling unit 22. The further heat sink 85 has a further cooling channel 95 through which coolant flows. Electrical connection terminals 105 that are provided for producing electrical connections between the further unit 80 to be cooled and the circuit board 75 can moreover be seen on the further unit 80 to be cooled. The unit 10 to be cooled also has electrical connection terminals for connection to the circuit board 75.

The cooling unit 22 shown in FIG. 2 is designed to supply coolant to a plurality of heat sinks and to discharge the coolant again after it has flowed through the heat sinks. In the example of FIG. 2, the cooling unit 22 is designed to supply coolant to both the heat sink 5 and the further heat sink 85 and subsequently to discharge it from both the heat sink 5 and the further heat sink 85. The cooling unit 22 is in particular designed to distribute the coolant evenly among the various heat sinks.

The further heat sink 85 is also fluidically connected to the cooling unit 22 when it is secured to the further receptacle 92. In the sectional view of FIG. 2, it can be seen that the further cooling channel 95 is connected via the further coolant discharge 100 and the further second fluid port 102 to the second flow channel 30, through which the coolant is discharged.

FIG. 1 shows that a plurality of cooling pins 65 that extend from the first cooling wall 50 into the cooling channel 35 can be arranged in the cooling channel 35 or in part of the cooling channel 35.

FIG. 1 also shows that the plurality of cooling pins 65 can comprise at least one cooling pin of a first category that is oriented in a first inclination direction that is inclined obliquely relative to a perpendicular to the first cooling wall 50.

FIG. 1 also shows that the cooling pins of the plurality of cooling pins 65 can be arranged such that one cooling pin of the plurality of cooling pins 65 does not intersect another cooling pin of the plurality of cooling pins 65.

FIG. 1 also shows that the plurality of cooling pins 65 can comprise at least one cooling pin of a second category that is oriented in a second inclination direction that is inclined obliquely relative to the perpendicular to the first cooling wall, wherein the second inclination direction is different from the first inclination direction. In this embodiment, the plurality of pins 65 comprises cooling pins of the first category, oriented in a first inclination direction, and cooling pins of the second category, oriented in a second inclination direction. The different orientation of the cooling pins creates a flow pattern in the cooling channel 35 which has proven advantageous for efficient heat dissipation.

FIG. 1 also that the plurality of cooling pins 65 can be arranged such that a cooling pin of the first category overlaps with a cooling pin of the second category at a viewing angle parallel to the cooling wall, in particular at a viewing angle of the coolant flow direction. ‘Overlapping’ here means that at least one cooling pin of the first category at least partially covers another cooling pin of the second category in the given viewing direction. Such an arrangement can improve the turbulence of the coolant at the cooling pins and consequently heat transfer from the cooling pins to the coolant.

FIG. 1 also shows that the plurality of cooling pins 65 can be arranged such that a cooling pin of the first category is interwoven with two cooling pins of the second category at a viewing angle parallel to the cooling wall, in particular at a viewing angle of the coolant flow direction. The term ‘interwoven’ here means that at least one first cooling pin of the first category at least partially covers a second cooling pin of the second category in the given viewing direction, and that the first cooling pin itself is also at least partially covered by a further cooling pin of the second category in the given viewing direction. Such an arrangement can further improve the turbulence of the coolant at the cooling pins and consequently heat transfer from the cooling pins to the coolant.

The circuit board 75 shown in FIG. 2, together with the units 10 and 80 to be cooled and the heat sinks 5 and 85 secured to the circuit board 75, forms a structural unit that can be placed on and taken back off the cooling unit 22 as a whole and is therefore releasably connected to the cooling unit 22. When this structural unit is placed on the cooling unit 22, the heat sinks 5, 85 attached to the units 10, 80 to be cooled are inserted into the corresponding receptacles 23, 92 of the cooling unit 22. Subsequently, the heat sinks 5, 85 are secured to the cooling unit 22 by way of at least one securing means 15, wherein fluidic connections for supplying and discharging coolant between the respective heat sinks 5, 85 and the cooling unit 22 are produced when the heat sinks 5, 85 are secured to the cooling unit 22. The cooling unit 22 is designed to supply all the heat sinks 5, 85 of the structural unit evenly with coolant and to discharge the coolant once it has flowed through the heat sinks 5, 85.

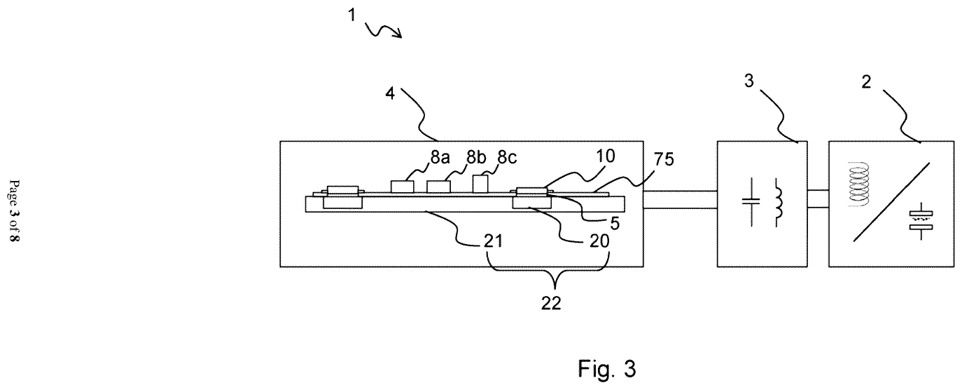

FIG. 3 shows an industrial process assembly 1, preferably a plasma process assembly or a heating assembly.

The industrial process assembly 1 has:
an electrical power converter 4,
a load 2, preferably a plasma process or heating process, e.g., an induction or microwave heating process, wherein the load 2 is electrically connected to the electrical power converter 4, such that the electrical power converter 4 can supply the load 2 with the required electrical power,
optionally an additional adaptation unit 3 which is connected between the power converter 4 and the load 2.

The power converter 4 has:
a heat sink 5, as described above and below,
a cooling unit 22, which, as described above and below, has one or more distribution units 20 and a carrier unit 21,
a circuit board 75,
a unit 10 to be cooled, in particular an electric unit, preferably a semiconductor assembly, preferably having a power semiconductor component,
further electronic components 8a, 8b, 8c,
   wherein the further electronic components 8a, 8b, 8c and the unit 10 to be cooled are arranged on or at a circuit board 75 and are connected to electrical contacts,
   wherein the unit 10 to be cooled is fixedly connected, in particular by a material bond, to the heat sink 5.

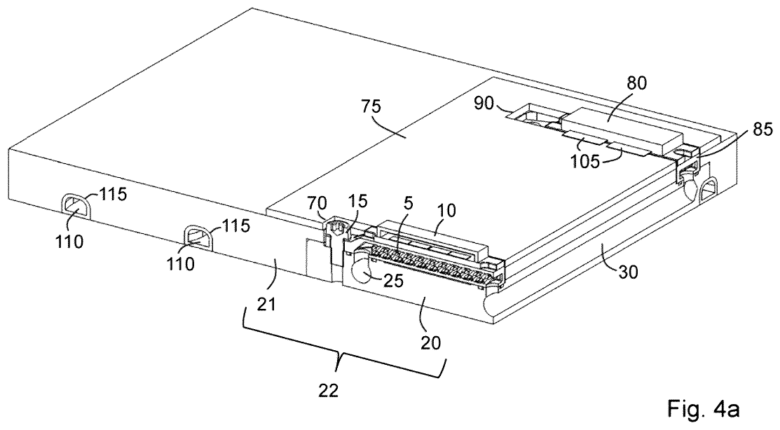

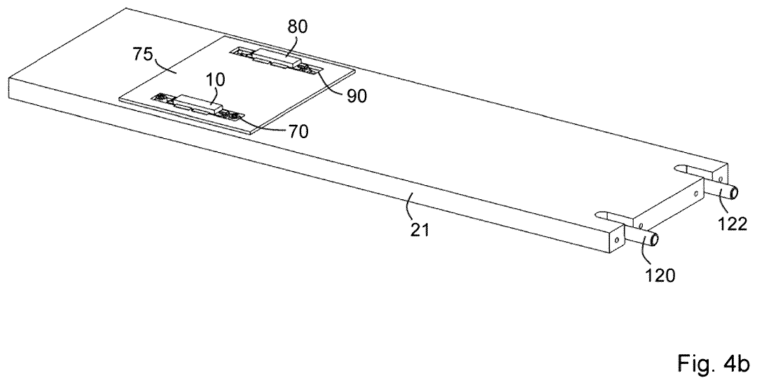

FIG. 4a shows another view of the circuit board 75 from an oblique angle above, in which part of the carrier unit 21 can be seen. Furthermore, in the sectional view of FIG. 4a, pipes 110 can be seen which are fitted into grooves 115 provided for this purpose on the underside of the carrier unit 21.

The heat sinks 5, 85 are preferably made of metal, more preferably of copper. Alternatively, the heat sinks 5, 85 could, for example, be made of stainless steel, nickel, or molybdenum. The carrier unit 21 can, for example, consist entirely of or partially comprises metal, but the carrier unit can also consist entirely of or partially comprise a plastics material. The carrier unit 21 preferably consists entirely of or partially comprises aluminum. The walls of the pipes 110 preferably consist of or comprise copper.

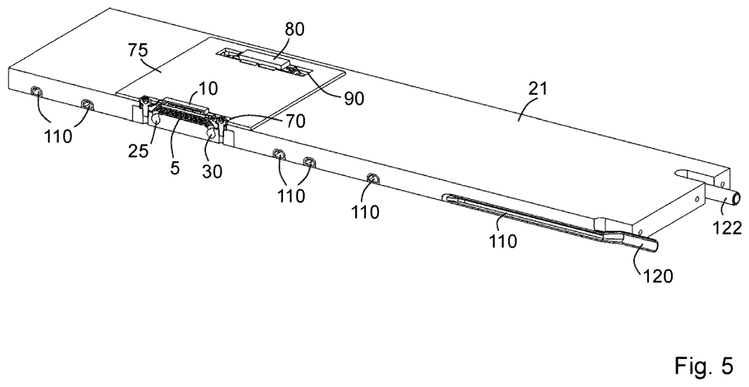

FIGS. 4b and 5 show the carrier unit 21 as a whole, the circuit board 75 with the units 10 and 80 to be cooled being visible. The carrier unit 21 is provided with a first coolant connection 120 for supplying coolant and a second coolant connection 122 for discharging coolant. The longitudinal section through the unit 10 to be cooled shown in FIG. 5 also shows the heat sink 5, the first flow channel 25 and the second flow channel 30. Furthermore, some of the pipes 110 arranged on the underside of the carrier unit 21 can be seen in the sectional view of FIG. 5.

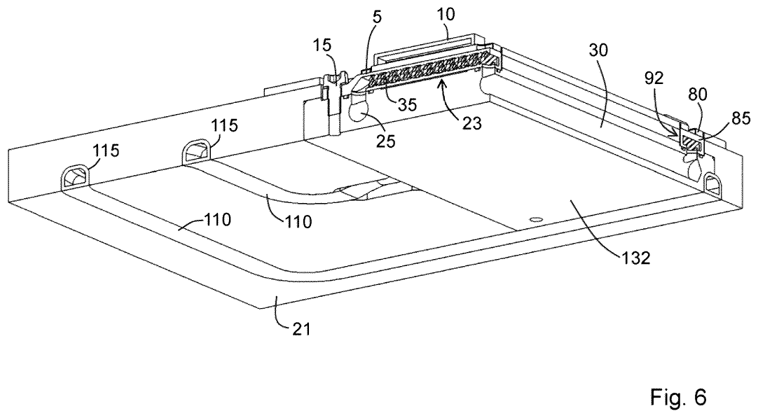

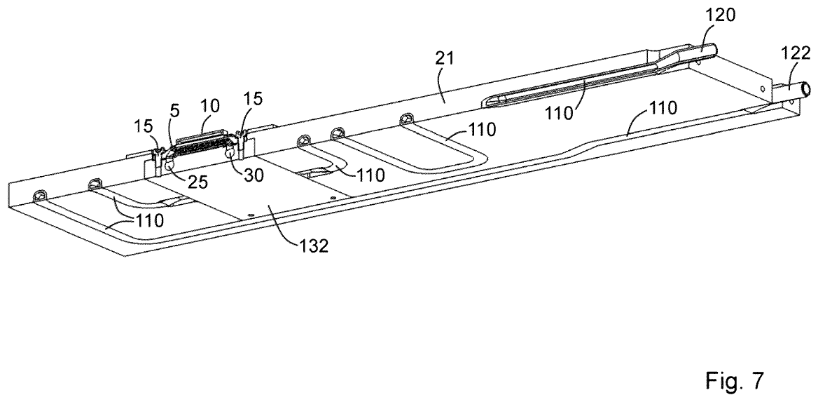

FIGS. 6 and 7 show two oblique views of the carrier unit 21 from below. FIG. 6 shows the units 10 and 80 to be cooled, as well as the heat sinks 5 and 85. FIGS. 6 and 7 show that the distribution unit is in the form of a cooling insert 132, wherein the cooling insert 132 preferably consists of or comprises a metal with high thermal conductivity, preferably copper. The cooling insert 132 is inserted into the carrier unit 21.

The receptacle 23 for the heat sink 5 and the further receptacle 92 for the further heat sink 85 are part of the cooling insert 132. The heat sink 5 is secured to the cooling insert 132 by way of at least one securing means 15. The heat sink 5 is preferably tightly screwed to the cooling insert 132. Using of a copper cooling insert 132 in those regions in which the heat sinks 5 and 85 are arranged enables improved heat dissipation from the heat sinks 5 and 85.

When using a cooling insert 132 made of copper, the structures provided for fluidically contacting the heat sinks 5 and 85 are arranged within the cooling insert 132. In this respect, the first flow channel 25, the first fluid port 41, the second flow channel 30, the second fluid port 46, and the further second fluid port 102 are formed within the cooling insert 132. The pipes 110, which are pressed into the grooves 115 provided for this purpose on the underside of the carrier unit 21, can furthermore be seen in FIG. 6 and FIG. 7. The pipe wall of the pipes 110 preferably consists of or comprises a metal with high thermal conductivity, preferably copper. The pipes 110 are furthermore preferably connected to the cooling insert 132 and are designed to supply cold coolant to the cooling insert 132 and to discharge heated coolant.

FIG. 7 shows the entire carrier unit 21 from the underside. In addition to the cooling insert 132 and the pipes 110 pressed into the grooves 115, FIG. 7 additionally shows the coolant connections 120 and 122 for supplying and discharging coolant.

The features disclosed in the above description and the drawings can be important both individually and in any combination for implementing the various configurations of the development.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A heat sink for dissipating heat from an electric unit to be cooled, the heat sink comprising:
a cooling channel;
a first cooling wall arranged on a side of the cooling channel facing the electric unit to be cooled;
a coolant feed and a coolant discharge which are both fluidically connected to the cooling channel configured for supplying and discharging cooling liquid,
wherein the heat sink is configured such that:
the electric unit to be cooled can be mechanically and thermally connected to the first cooling wall,
the heat sink can be releasably secured to a cooling unit comprising a first fluid port and a second fluid port,
a first fluidic connection is configured to be produced between the coolant feed of the heat sink and the first fluid port of the cooling unit when the heat sink is secured to the cooling unit, and a second fluidic connection is configured to be produced between the coolant discharge of the heat sink and the second fluid port of the cooling unit when the heat sink is secured to the cooling unit,
when the heat sink is secured to the cooling unit a fluid-tight seal is simultaneously created between the first fluidic connection and the second fluidic connection, and
the heat sink can be mechanically fixedly connected to the electric unit to be cooled, the electric unit to be cooled being fixedly connected to a circuit board via a connection.

2. The heat sink according to claim 1, wherein the heat sink is configured to be releasably secured to the cooling unit by at least one securing means.

3. The heat sink according to claim 1, wherein the fluid-tight seal of the first fluidic connection and the second fluidic connection is configured to be produced with at least one securing means accessible from a side of the first cooling wall.

4. The heat sink according to claim 1, wherein the heat sink is configured such that, when the heat sink is secured to the cooling unit, a cooling flow is configured to be produced from the first fluid port to the coolant feed via the cooling channel and the coolant discharge to the second fluid port.

5. The heat sink according to claim 1, wherein the heat sink comprises metal.

6. An electronic assembly comprising:
the heat sink according to claim 1; and
an electric unit to be cooled which is mechanically fixedly connected to the heat sink and is configured to be simultaneously fixedly connected to a circuit board by soldering.

7. The electronic assembly according to claim 6, wherein the electric unit to be cooled is connected to the heat sink by at least one of the following: at least one soldered connection, at least one welded connection, and/or sintering.

8. The electronic assembly according to claim 6, further comprising the circuit board to which the electric unit to be cooled is mechanically fixedly connected.

9. A cooling unit configured to supply a heat sink which has a coolant feed and a coolant discharge with cooling liquid,, the cooling unit comprising:
a first flow channel and a second flow channel;
a first fluid port which is fluidically connected to the first flow channel; and
a second fluid port which is fluidically connected to the second flow channel,
wherein the cooling unit is configured such that:
the heat sink can be releasably secured to the cooling unit,
a first fluidic connection is configured to be produced between the coolant feed of the heat sink and the first fluid port of the cooling unit when the heat sink is secured to the cooling unit, and a second fluidic connection is configured to be produced between the coolant discharge of the heat sink and the second fluid port of the cooling unit when the heat sink is secured to the cooling unit,
when the heat sink is secured to the cooling unit a fluid-tight seal is simultaneously created between the first fluidic connection and the second fluidic connection, and
the heat sink can be mechanically fixedly connected to an electric unit to be cooled that is fixedly connected to a circuit board via a connection.

10. The cooling unit according to claim 9, wherein the cooling unit is configured to supply the cooling liquid to a plurality of heat sinks and to discharge the cooling liquid from the plurality of heat sinks.

11. The cooling unit according to claim 9, further comprising:
a distribution unit having the first fluid port and the second fluid port.

12. The cooling unit according to claim 11, wherein the distribution unit is configured as a cooling insert which comprises a material which has a higher thermal conductivity compared to other regions of the cooling unit.

13. The cooling unit according to claim 9, further comprising
a carrier unit.

14. A cooling device, comprising
the heat sink according to claim 1.

15. An electrical power converter for an industrial process assembly, comprising:
the heat sink according to claim 1;
the circuit board;
the electric unit to be cooled; and
further electronic components,
wherein the further electronic components and the electric unit to be cooled are arranged on or at the circuit board and are connected to electrical contacts, and
wherein the unit to be cooled has a fixed materially bonded connection to the heat sink and the electric unit to be cooled is simultaneously fixedly connected to the circuit board by a number of solder connections.

16. The electrical power converter according to claim 15, further comprising a cooling unit.

17. The electrical power converter according to claim 16, further comprising a cooling device.

18. The electrical power converter according to claim 15, further comprising a further heat sink configured identically to the heat sink.

19. The electrical power converter according to claim 15, further comprising an electronic assembly and a further electronic assembly,
wherein the electronic assembly includes the heat sink and the electric unit to be cooled, and
wherein the further electronic assembly includes the further heat sink and the electronic unit to be cooled.

20. A method for assembling a cooling device, comprising:
providing a heat sink for dissipating heat from an electric unit to be cooled, wherein the heat sink comprises a cooling channel, a coolant feed fluidically connected to the cooling channel and a coolant discharge fluidically connected to the cooling channel;
providing a cooling unit comprising a first fluid port and a second fluid port; and
releasably securing the heat sink to the cooling unit,
wherein, when the heat sink is secured to the cooling unit, a first fluidic connection is produced between the coolant feed of the heat sink and the first fluid port of the cooling unit, and a second fluidic connection is produced between the coolant discharge of the heat sink and the second fluid port of the cooling unit, and
wherein, when the heat sink is secured to the cooling unit, a fluid-tight seal is simultaneously created between the first fluidic connection and the second fluidic connection.
